(19) United States
(12) Patent Application Publication
(10) Pub. No.: US 2026/0023330 A1
(43) Pub. Date: Jan. 22, 2026

(54) FOCUS DETECTION SYSTEM FOR MUTUALLY-COHERENT ILLUMINATION METROLOGY

(71) Applicant: KLA Corporation, Milpitas, CA (US)

(72) Inventors: David Koprivica, Petah Tikva (RS); Nireekshan K. Reddy, Tel Aviv (IL); Vladimir Levinski, Migdal HaEmek (IL); Yonatan Vaknin, Yoqneam Illit (IL); Andrew V. Hill, Sunriver, OR (US); Alon Alexander Volfman, Migdal Haemek (IL)

(21) Appl. No.: 19/264,356

(22) Filed: Jul. 9, 2025

Related U.S. Application Data
(60) Provisional application No. 63/672,261, filed on Jul. 17, 2024.

(51) Int. Cl. G03F 7/00

(52) U.S. Cl. CPC G03F 7/70641; G03F 7/70633

(57) ABSTRACT

A focus detection system may include an illumination system with one or more illumination lenses that may direct a first illumination beam and a second illumination beam to a sample at opposing azimuth angles. The system may include an imaging system with one or more collection lenses that may image the sample onto one or more detectors. A controller with one or more processors may be configured to execute program instructions that may cause the processors to determine a lateral shift between locations of features on the sample imaged by different combinations of the first and second illumination beams. The instructions may further cause the processors to generate a measurement of a focal position of the sample based on the lateral shift.

### CROSS-REFERENCE TO RELATED APPLICATIONS

The present application claims the benefit under 35 U.S.C. § 119(e) of U.S. Provisional Application Ser. No. 63/672,261, filed Jul. 17, 2024, entitled FOCUS DETECTION SYSTEM IN MUTUALLY COHERENT OBLIQUE ILLUMINATION SCHEME, which is incorporated herein by reference in the entirety.

### TECHNICAL FIELD

The present disclosure relates to optical metrology systems, and more particularly to a focus detection system for mutually-coherent illumination metrology.

### BACKGROUND

Optical metrology systems are widely used in semiconductor manufacturing to measure critical dimensions, overlay, and other parameters of structures on wafers. As feature sizes continue to shrink and manufacturing tolerances tighten, there is an ongoing need for improved metrology techniques that can provide accurate measurements at high throughput.

Focus detection and control is critical for proper optical metrology system operation. Proper focus helps ensure that the metrology target is imaged clearly onto the detector, enabling precise measurements. However, focus detection can be challenging, particularly for advanced metrology techniques that use specialized illumination schemes. There is therefore a need to develop systems and methods addressing the above challenges.

### SUMMARY

In some embodiments, a focus detection system is disclosed. The focus detection system may include an illumination system including one or more illumination lenses configured to direct a first illumination beam and a second illumination beam to a sample at opposing azimuth angles. The system may include an imaging system including one or more collection lenses configured to image the sample onto one or more detectors. The system may also include a controller including one or more processors configured to execute program instructions causing the one or more processors to determine a lateral shift between locations of features on the sample imaged by different configurations of the first illumination beam and the second illumination beam, and generate a measurement of a focal position of the sample based on the lateral shift.

In some embodiments, the one or more illumination lenses may direct the first illumination beam and the second illumination beam to the sample by illumination optics outside of a numerical aperture (NA) of an objective lens in the imaging system.

In some embodiments, determining the lateral shift between locations of features on the sample imaged by different combinations of the first illumination beam and the second illumination beam may include receiving a first image of the features on the sample imaged with the first illumination beam, receiving a second image of the features on the sample imaged with the second illumination beam, and determining the lateral shift based on the first image and the second image.

In some embodiments, the one or more detectors may include a single detector, and the first image and the second image may be generated by the single detector sequentially based on sequential illumination of the sample with the first illumination beam and the second illumination beam.

In some embodiments, the imaging system may include one or more splitting optics to direct light from the sample associated with the first illumination beam along a first path for generation of the first image and to direct light from the sample associated with the second illumination beam along a second path for generation of the second image. The first image and the second image may be generated simultaneously based on simultaneous illumination of the sample with the first illumination beam and the second illumination beam.

In some embodiments, the first image and the second image may be generated on separate detectors of the one or more detectors.

In some embodiments, the first image and the second image may be generated on nonoverlapping regions of a common detector of the one or more detectors.

In some embodiments, the one or more splitting optics may include a splitting prism located in a collection pupil of the imaging system.

In some embodiments, the first image may be generated based on first-order diffraction of the first illumination beam by the sample, and the second image may be generated based on first-order diffraction of the second illumination beam by the sample.

In some embodiments, the first image may be generated based on zero-order diffraction of the first illumination beam by the sample, and the second image may be generated based on zero-order diffraction of the second illumination beam by the sample.

In some embodiments, the one or more illumination lenses may direct the first illumination beam and the second illumination beam to the sample by illumination optics outside of a numerical aperture of an objective lens in the imaging system. The illumination optics may include beamsplitters to collect the zero-order diffraction of the first illumination beam and the zero-order diffraction of the second illumination beam for generation of the first image and the second image.

In some embodiments, the first image may be generated based on zero-order sidelobes associated with the first illumination beam from the sample, and the second image may be generated based on zero-order sidelobes associated with the second illumination beam from the sample.

In some embodiments, the first illumination beam and the second illumination beam may be mutually coherent at one or more first wavelengths, and the first illumination beam may include one or more second wavelengths. Determining the lateral shift between locations of features on the sample imaged by different combinations of the first illumination beam and the second illumination beam may include receiving a single image of the features on the sample. The single image may include a first sub-image of the features generated with the one or more first wavelengths from the first illumination beam and the second illumination beam, and may further include a second sub-image of the features generated with the one or more second wavelengths from the first illumination beam. The lateral shift may be determined based on the first sub-image and the second sub-image.

In some embodiments, the first sub-image may be generated based on first-order diffraction of the one or more first wavelengths by the sample, and the second sub-image may be generated based on first-order diffraction of the one or more second wavelengths by the sample.

In some embodiments, the first sub-image may be generated based on zero-order diffraction of the one or more first wavelengths by the sample, and the second sub-image may be generated based on zero-order diffraction of the one or more second wavelengths by the sample.

In some embodiments, the one or more illumination lenses may direct the first illumination beam and the second illumination beam to the sample by illumination optics outside of a numerical aperture of an objective lens in the imaging system. The illumination optics may include beamsplitters to collect the zero-order diffraction of the first illumination beam and the zero-order diffraction of the second illumination beam for generation of the first sub-image and the second sub-image.

In some embodiments, the first sub-image may be generated based on zero-order sidelobes associated with the one or more first wavelengths by the sample, and the second sub-image may be generated based on zero-order sidelobes associated with the one or more second wavelengths by the sample.

In some embodiments, a focus detection method is disclosed. The method may include directing a first illumination beam and a second illumination beam to a sample at opposing azimuth angles with an illumination system, imaging the sample onto one or more detectors with different configurations of the first illumination beam and the second illumination beam, determining a lateral shift between locations of features on the sample imaged by different combinations of the first illumination beam and the second illumination beam, and generating a measurement of a focal position of the sample based on the lateral shift.

In some embodiments, a metrology system is disclosed. The metrology system may include an illumination system including one or more illumination lenses configured to direct a first illumination beam and a second illumination beam to a sample at opposing azimuth angles, an imaging system including one or more collection lenses configured to image the sample onto one or more detectors, one or more actuators to adjust a focal position of the sample, and a controller including one or more processors configured to execute program instructions causing the one or more processors to determine a lateral shift between locations of features on the sample imaged by different configurations of the first illumination beam and the second illumination beam, generate a measurement of the focal position of the sample based on the lateral shift, direct the one or more actuators to adjust the focal position of the sample to a desired setting based on the measurement, receive one or more images of the sample from at least one of the one or more detectors, and generate one or more metrology measurements of the sample based on the one or more images.

In some embodiments, determining the lateral shift between locations of features on the sample imaged by different combinations of the first illumination beam and the second illumination beam may include receiving a first image of the features on the sample imaged with the first illumination beam, receiving a second image of the features on the sample imaged with the second illumination beam, and determining the lateral shift based on the first image and the second image.

In some embodiments, the first illumination beam and the second illumination beam may be mutually coherent at one or more first wavelengths, and the first illumination beam may include one or more second wavelengths. Determining the lateral shift between locations of features on the sample imaged by different combinations of the first illumination beam and the second illumination beam may include receiving a single image of the features on the sample. The single image may include a first sub-image of the features generated with the one or more first wavelengths from the first illumination beam and the second illumination beam, and may further include a second sub-image of the features generated with the one or more second wavelengths from the first illumination beam. The lateral shift may be determined based on the first sub-image and the second sub-image.

In some embodiments, the one or more metrology measurements may include one or more overlay measurements.

It is to be understood that both the foregoing general description and the following detailed description are exemplary and explanatory only and are not necessarily restrictive of the invention as claimed. The accompanying drawings, which are incorporated in and constitute a part of the specification, illustrate embodiments of the invention and together with the general description, serve to explain the principles of the invention.

### BRIEF DESCRIPTION OF FIGURES

The numerous advantages of the disclosure may be better understood by those skilled in the art by reference to the accompanying figures.

FIG. 1A illustrates a block diagram of a focusing system, in accordance with one or more embodiments of the present disclosure.

FIG. 1B illustrates a block diagram of a metrology system, in accordance with one or more embodiments of the present disclosure.

FIG. 1C illustrates a schematic view of a focusing system, in accordance with one or more embodiments of the present disclosure.

FIG. 1D illustrates a focusing system with multiple detectors, in accordance with one or more embodiments of the present disclosure.

FIG. 1E illustrates a focusing system for detecting focus position of a sample, in accordance with one or more embodiments of the present disclosure.

FIG. 2A illustrates a system diagram showing diffraction components in a collection pupil of an optical system, in accordance with one or more embodiments of the present disclosure.

FIG. 2B illustrates a system diagram showing two images captured using different illumination conditions, in accordance with one or more embodiments of the present disclosure.

FIG. 3 illustrates a system diagram showing diffraction components and blockers in a collection pupil of a focus detection system, in accordance with one or more embodiments of the present disclosure.

FIG. 4 illustrates a system diagram showing illumination pupil distributions and corresponding image configurations, in accordance with one or more embodiments of the present disclosure.

FIG. 5 illustrates a flowchart of a method for focus detection, in accordance with one or more embodiments of the present disclosure.

### DETAILED DESCRIPTION

Reference will now be made in detail to the subject matter disclosed, which is illustrated in the accompanying drawings. The present disclosure has been particularly shown and described with respect to certain embodiments and specific features thereof. The embodiments set forth herein are taken to be illustrative rather than limiting. It should be readily apparent to those of ordinary skill in the art that various changes and modifications in form and detail may be made without departing from the spirit and scope of the disclosure.

Embodiments of the present disclosure are directed to systems and methods for focus detection in optical metrology systems utilizing pairs of illumination beams directed to a sample at opposing azimuth incidence angles. In particular, embodiments are directed to determining focal position based on lateral shift measurements between images generated using different combinations of illumination beams directed at a sample from opposing azimuth angles.

The systems and methods disclosed herein may provide focus measurements for any type of optical system that utilizes two illumination beams directed at a sample from opposing angles. For example, the systems and methods disclosed herein may provide focus measurements for optical metrology tools such as, but not limited to, optical metrology tools utilizing one or more pairs of mutually-coherent illumination beams. The use of mutually-coherent illumination for overlay metrology is generally described in U.S. Pat. No. 12,032,300 issued on Jul. 9, 2024 and U.S. patent application Ser. No. 18/978,376 filed on Dec. 12, 2024, both of which are incorporated herein by reference in their entireties.

In embodiments, a focus detection system may include an illumination system and an imaging system. The illumination system may include one or more illumination lenses configured to direct a first illumination beam and a second illumination beam to a sample at opposing azimuth angles. The imaging system may include one or more collection lenses configured to image the sample onto one or more detectors.

In this configuration, focus may be determined by analyzing lateral shifts of imaged features on the sample when illuminated by different combinations of the first and second illumination beams. The focus measurement may capture a deviation of a feature to be imaged relative to a focal plane of the imaging system. In some aspects, the measurement may include both a magnitude and a direction (e.g., sign) of any defocus. This information may allow the system to determine not only how far the sample is from the optimal focal position, but also whether it is above or below the focal plane.

In some embodiments, focus is determined based on two separate images generated using different illumination conditions, where the two images may be generated sequentially or simultaneously. In some embodiments, focus is determined based on a single image, where the illumination beams may have different properties (e.g., wavelengths) that may provide a sign of any measured defocus.

The images used for focus detection may be based on any diffraction components that provide a lateral shift from the sample that may be indicative of a focal position of the sample. In some cases, first-order diffraction may be collected and used to form the images. In other implementations, zero-order diffraction or zero-order sidelobes may be utilized. The choice of which diffraction components to use may depend on factors such as the specific sample structure, desired sensitivity, and system configuration.

Focus detection based on lateral shift measurements between images generated using pairs of opposing illumination beams may provide several advantages over existing focus detection techniques. For example, the disclosed approach may enable focus detection without requiring additional dedicated focus detection hardware. This may simplify system architecture, reduce costs, and avoid potential alignment issues associated with separate focus subsystems. Additionally, by utilizing the same illumination and imaging components used for metrology measurements, focus detection may be performed simultaneously with or as part of the metrology process.

The systems and method disclosed herein may provide focus detection based on imaging of any features on a sample. In some cases, focus detection is provided by imaging a metrology target (e.g., an overlay target) to be characterized by a metrology tool. For example, the systems and methods may be compatible with advanced imaging metrology (AIM) targets, Moiré targets, and robust-AIM (r-AIM) overlay targets, or any other target design.

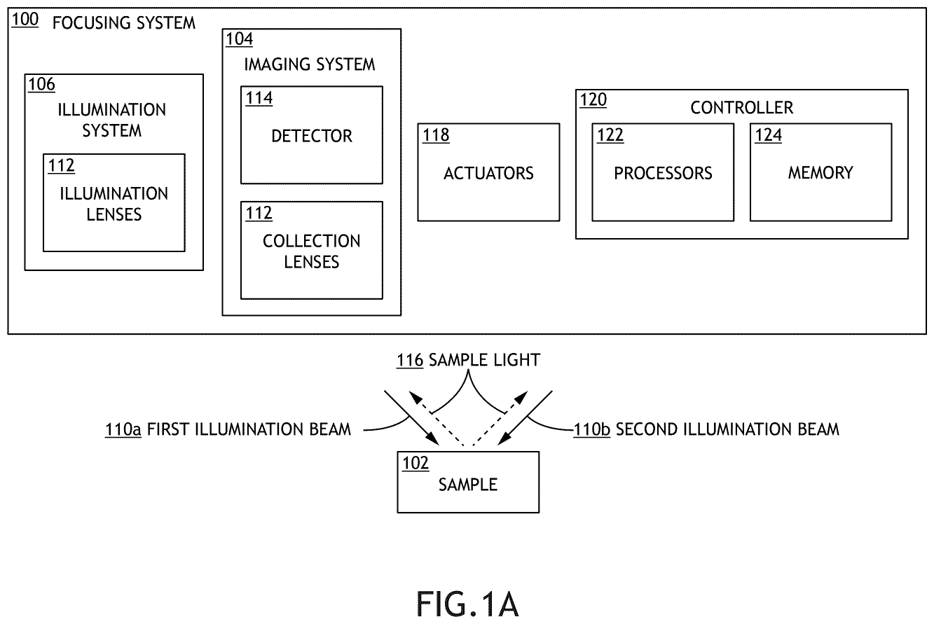

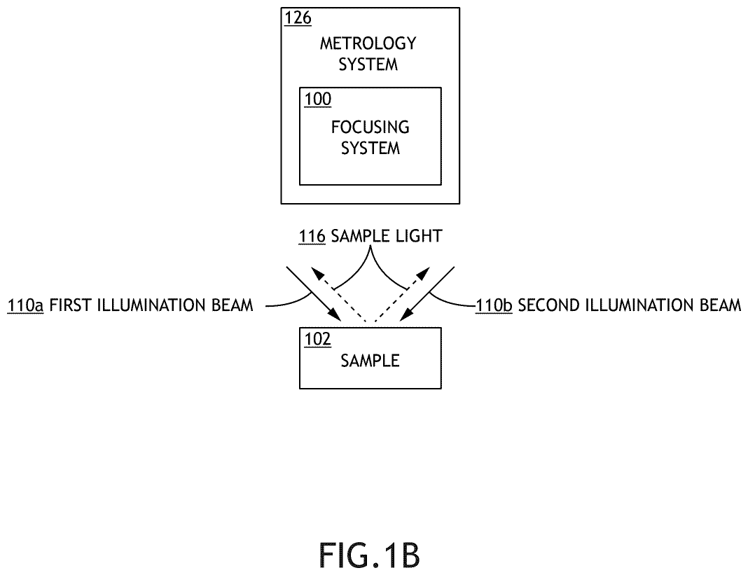

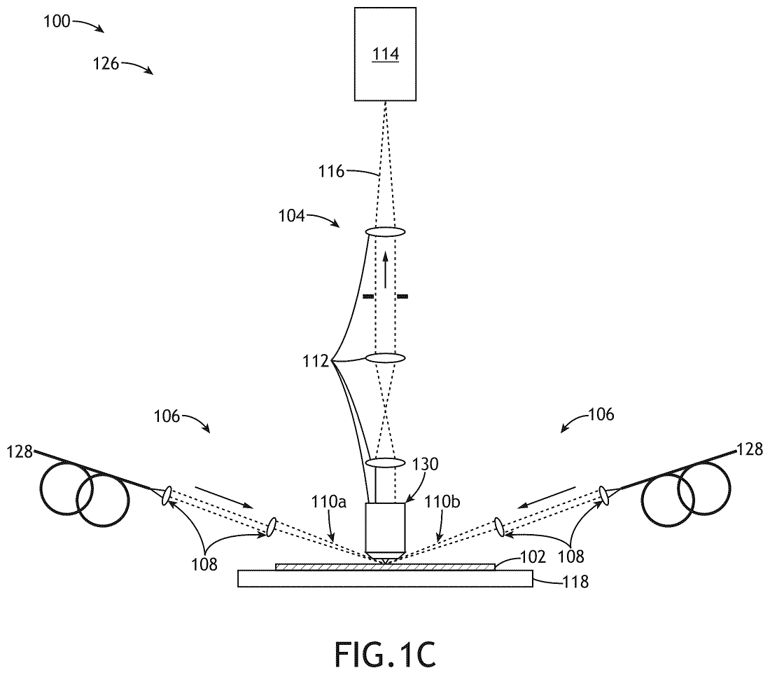

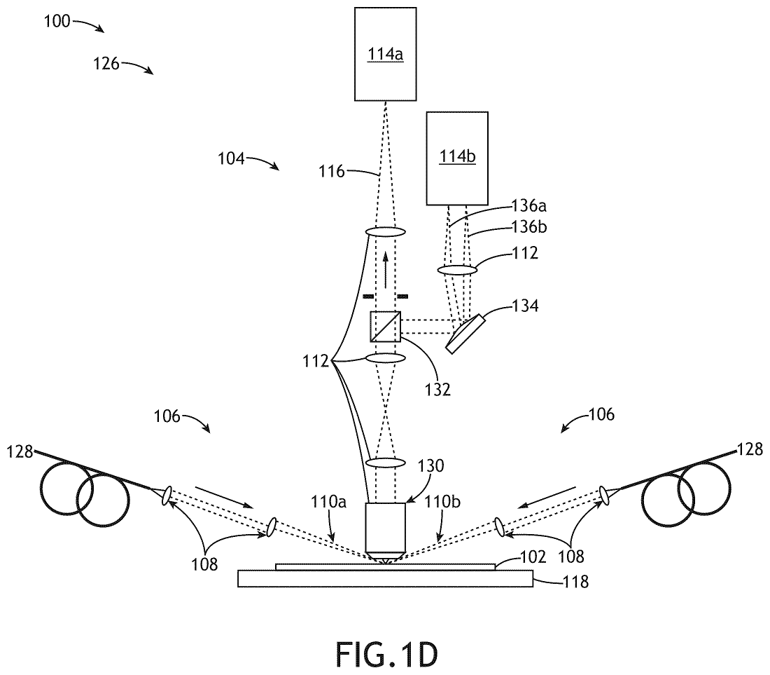

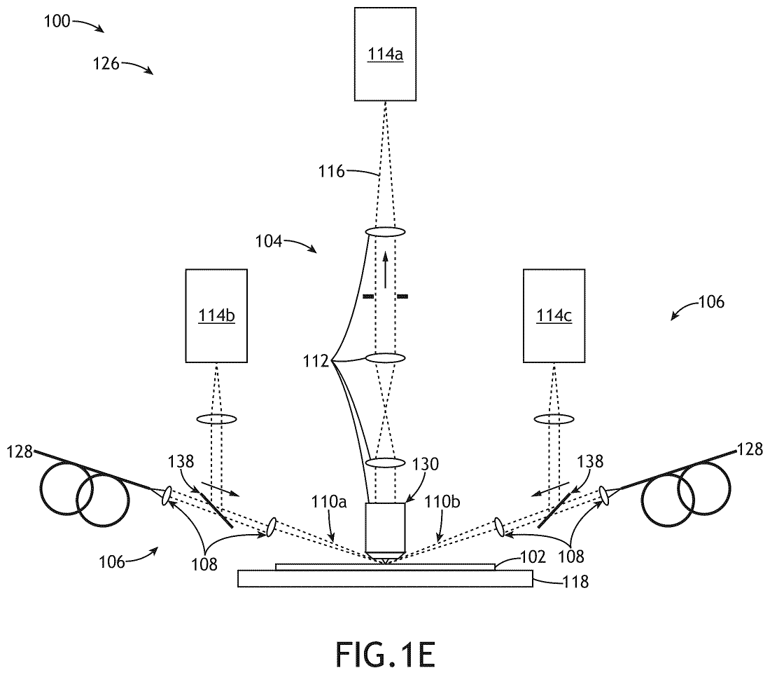

FIG. 1A illustrates a block diagram of a focusing system 100, in accordance with one or more embodiments of the present disclosure.

In embodiments, the focusing system 100 includes an illumination system 106, an imaging system 104, actuators 118, and a controller 120. The illumination system 106 may include illumination lenses 108 configured to direct a first illumination beam 110a and a second illumination beam 110b toward a sample 102. The first illumination beam 110a and the second illumination beam 110b may be directed to the sample 102 at opposing azimuth angles. The imaging system 104 may include collection lenses 112 and a detector 114. In this way, the collection lenses 112 may collect sample light 116 from the sample 102 and direct the sample light 116 to the detector 114. The detector 114 may capture one or more images based on the collected sample light 116 associated with different combinations of the first illumination beam 110a and the second illumination beam 110b. The focusing system may include multiple pairs of illumination beams directed at the sample at different opposing azimuth incidence angles. In this way, any descriptions or examples of a single pair of illumination beams should not be interpreted as limiting the scope of the present disclosure.

In embodiments, the focusing system 100 includes one or more actuators 118 to adjust a focal position of the sample 102. The actuators 118 may include any component or combination of components suitable for adjusting the focal position of the sample 102. For example, the actuators 118 may adjust positions of the sample 102 and/or components of the imaging system 104, such as an objective lens, to provide modification of the focal position of the sample 102.

In embodiments, the focusing system 100 includes a controller 120, which may be communicatively coupled with any component of the focusing system 100 such as, but not limited to, the one or more detectors 114 or the one or more actuators 118. The controller 120 may include processors 122 and memory 124, where the memory 124 may store instructions and data used by the processors 122. For example, the processors 122 may execute instructions stored in the memory 124 to perform various steps disclosed herein.

The one or more processors 122 of the controller 120 may include any processor or processing element known in the art. For the purposes of the present disclosure, the term “processor” or “processing element” may be broadly defined to encompass any device having one or more processing or logic elements (e.g., one or more micro-processor devices, one or more application specific integrated circuit (ASIC) devices, one or more field programmable gate arrays (FPGAs), or one or more digital signal processors (DSPs)). In this sense, the one or more processors 122 may include any device configured to execute algorithms and/or instructions (e.g., program instructions stored in memory). In some embodiments, the one or more processors 122 may be embodied as a desktop computer, mainframe computer system, workstation, image computer, parallel processor, networked computer, or any other computer system configured to execute a program configured to operate or operate in conjunction with the system, as described throughout the present disclosure.

The memory 124 may include any storage medium known in the art suitable for storing program instructions executable by the associated one or more processors 122. For example, the memory 124 may include a non-transitory memory medium. By way of another example, the memory 124 may include, but is not limited to, a read-only memory (ROM), a random-access memory (RAM), a magnetic or optical memory device (e.g., disk), a magnetic tape, a solid-state drive and the like. In some embodiments, the memory 124 may be housed in a common controller housing with the one or more processors 122. In some embodiments, the memory 124 may be located remotely with respect to the physical location of the one or more processors 122 and controller 120. For instance, the one or more processors 122 of the controller 120 may access a remote memory (e.g., server), accessible through a network (e.g., internet, intranet and the like).

In some cases, the controller 120 may directly or indirectly (e.g., via control signals) perform any steps described in the present disclosure. For example, the controller 120 may be configured to determine a lateral shift between locations of features on the sample 102 imaged by different combinations of the first illumination beam 110a and the second illumination beam 110b. As another example, the controller 120 may generate a measurement of a focal position of the sample 102 based on the lateral shift. In some examples, the controller 120 may direct the actuators 118 to adjust the focal position to a desired setting based on the measurement.

Referring now to FIG. 1B, in some embodiments, the focusing system 100 may be incorporated into a metrology system 126. FIG. 1B illustrates a block diagram of a metrology system 126, in accordance with one or more embodiments of the present disclosure.

In embodiments, the focusing system 100 and the metrology system 126 may share various components such as, but not limited to, the illumination system 106, the first illumination beam 110a and second illumination beam 110b, the imaging system 104, and/or the one or more detectors 114. This shared component architecture mitigates alignment or calibration issues and thus enables high focus positioning accuracy for a metrology measurement. Further, this architecture may reduce component count, reduce costs, and promote efficient use of light.

Referring now to FIGS. 1C-4, various implementations of the focusing system 100 for focus detection are described in greater detail.

Focus detection based on lateral shifts of imaged features using different configurations of the first illumination beam 110a and the second illumination beam 110b may be implemented in numerous ways within the scope of the present disclosure. In some embodiments, two images are generated, where a first image is generated based on the first illumination beam 110a and the second image is generated based on the second illumination beam 110b. In these implementations, lateral shifts of features on the sample 102 between the first image and the second image are indicative of focal position. In some embodiments, a single image is generated that includes a first sub-image associated with a first illumination configuration and a second sub-image associated with a second illumination configuration. For example, the first sub-image and the second sub-image may be incoherently superimposed in the single image. In these configurations, lateral shifts of features on the sample 102 between the first sub-image and the second sub-image are indicative of focal position.

FIG. 1C illustrates a schematic view of a focusing system 100 including a single detector 114. The focusing system 100 shown in FIG. 1C may be suitable for sequential imaging of the sample 102 using different illumination configurations. Further, FIG. 1C may depict a metrology system 126 with an integrated focusing system 100.

The illumination system 106 may include any number or type of optical elements suitable for directing a first illumination beam 110a and a second illumination beam 110b to the sample 102 at opposing azimuth incidence angles. For example, the illumination system 106 may include one or more illumination lenses 108 to focus the first illumination beam 110a and the second illumination beam 110b on the sample 102.

The first illumination beam 110a and the second illumination beam 110b may be generated by any illumination source known in the art, which may optionally be a part of the focusing system 100 or the metrology system 126. In some embodiments, the first illumination beam 110a and the second illumination beam 110b are mutually coherent (e.g., mutually temporally coherent and/or mutually spatially coherent).

Further, the first illumination beam 110a and the second illumination beam 110b may have any spectrum such as, but not limited to, extreme ultraviolet (EUV) wavelengths, ultraviolet (UV) wavelengths, visible wavelengths, or infrared (IR) wavelengths. Further, the illumination source may be a broadband source, a narrowband source, and/or a tunable source.

In some embodiments, the illumination source includes a broadband plasma (BBP) illumination source. In this regard, the first illumination beam 110a and the second illumination beam 110b may include radiation emitted by a plasma. For example, a BBP illumination source may include, but is not required to include, one or more pump sources (e.g., one or more lasers) configured to focus into the volume of a gas, causing energy to be absorbed by the gas in order to generate or sustain a plasma suitable for emitting radiation. Further, at least a portion of the plasma radiation may be utilized as the first illumination beam 110a and the second illumination beam 110b.

In some embodiments, the illumination source may include any laser system known in the art capable of emitting radiation in the infrared, visible, or ultraviolet portions of the electromagnetic spectrum.

The illumination source may further produce the first illumination beam 110a and the second illumination beam 110b having any temporal profile. For example, the illumination source may produce continuous-wave (CW) illumination, pulsed illumination, or modulated illumination. Additionally, the first illumination beam 110a and the second illumination beam 110b may be delivered from the illumination source via free-space propagation or guided light (e.g., an optical fiber 128, a light pipe, or the like).

The illumination source may further delivery the first illumination beam 110a and the second illumination beam 110b either as free-space beams or through optical fibers. For example, FIG. 1C depicts the first illumination beam 110a and the second illumination beam 110b being delivered through optical fibers 128.

In some cases, as shown in FIG. 1C, the illumination lenses 108 may direct the first illumination beam 110a and the second illumination beam 110b to the sample 102 by illumination optics outside of a numerical aperture of an objective lens 130 in the imaging system 104. Such a configuration may be referred to as an outside-the-lens (OTL) arrangement. In some embodiments, although not shown, the illumination lenses 108 may direct the first illumination beam 110a and the second illumination beam 110b to the sample 102 through the objective lens 130 of the imaging system 104. This configuration may be referred to as a through-the-lens (TTL) arrangement.

In some embodiments, the illumination system 106 includes one or more illumination-conditioning optics to control properties of the first illumination beam 110a and the second illumination beam 110b such as, but not limited to, polarization, intensity, spectrum, beam size, beam shape, or incidence angle (e.g., altitude and/or azimuth incidence angle). For example, the illumination-conditioning optics may include, but are not limited to, polarizers, spectral filters, intensity filters, spatial filters, homogenizers, or apodizers.

The imaging system 104 may include any number or type of components suitable for imaging the sample 102 onto the one or more detectors 114. For example, the objective lens 130 may collect sample light 116 emanating from the sample 102 in response to illumination with the first illumination beam 110a and/or the second illumination beam 110b, where the sample light 116 may include diffracted light (e.g., one or more diffraction orders), scattered light, or reflected light. For example, in an OTL arrangement as shown in FIG. 1C, the objective lens 130 may collect diffracted light from a target with periodic features, but zero-order diffraction may not be collected. As another example, in a TTL arrangement, both zero-order diffraction and higher-order diffraction may be collected by the objective lens 130. The imaging system 104 may then include additional collection lenses 112 to image the sample 102 onto the one or more detectors 114 based on at least a portion of the sample light 116 captured by the objective lens 130. In some embodiments, the illumination system 106 includes one or more collection-conditioning optics to control properties of the sample light 116 such as, but not limited to, polarization, intensity, spectrum, beam size, beam shape, or incidence angle (e.g., altitude and/or azimuth incidence angle). For example, the collection-conditioning optics may include, but are not limited to, polarizers, spectral filters, intensity filters, spatial filters, homogenizers, or apodizers.

FIG. 1D illustrates a focusing system 100 providing simultaneous imaging with different configurations, in accordance with one or more embodiments of the present disclosure. The focusing system 100 shown in FIG. 1D is a variation of FIG. 1C suitable for simultaneously generating two images of the sample 102 (e.g., a first image and a second image) with different illumination conditions selected to provide lateral shifts between imaged features in the two images. In this way, descriptions of components common to FIGS. 1C and 1D may be extended to FIGS. 1D.

As shown in FIG. 1D, the focusing system 100 (and/or a metrology system 126 with an integrated focusing system 100) may include various splitting optics to direct sample light 116 associated with the first illumination beam along a first path for generation of the first image and to direct light from the sample associated with the second illumination beam along a second path for generation of the second image. For example, FIG. 1D depicts a configuration including a beamsplitter 132 to split the sample light 116 into a separate focus-detection channel, where the focus-detection channel includes pupil-splitting optics 134 configured to direct portions of the sample light 116 in different regions of a collection pupil to different detectors 114. For example, the pupil-splitting optics 134 may direct sample light 116 associated with the first illumination beam 110a along a first path 136a for generation of a first image and directs sample light 116 associated with the second illumination beam 110b along a second path 136b for generation of a second image. In this configuration, the first image and the second image may either be generated using a single detector 114 or separate detectors 114. For example, FIG. 1D illustrates a configuration in which the first image and the second image are generated in nonoverlapping regions of a detector 114b, where lateral shifts between the imaged features in the first image and the second image may be determined after a calibration at a zero-focus position. The detector 114a in FIG. 1D may then simultaneously generate an image of the sample for the purposes of generating a metrology measurement (e.g., when the focusing system 100 is integrated into a metrology system 126). As another example, though not shown, the focusing system 100 may include two detectors, where one detector generates the first image and another detector generates the second image.

The pupil-splitting optics 134 may include any number or type of optical components designed to separate and direct different portions of the sample light 116 along different paths. In some embodiments, the pupil-splitting optics 134 may include a splitting prism (e.g., a knife-edge prism), mirrors, or any other suitable components positioned in the collection pupil to divide the light into two distinct paths.

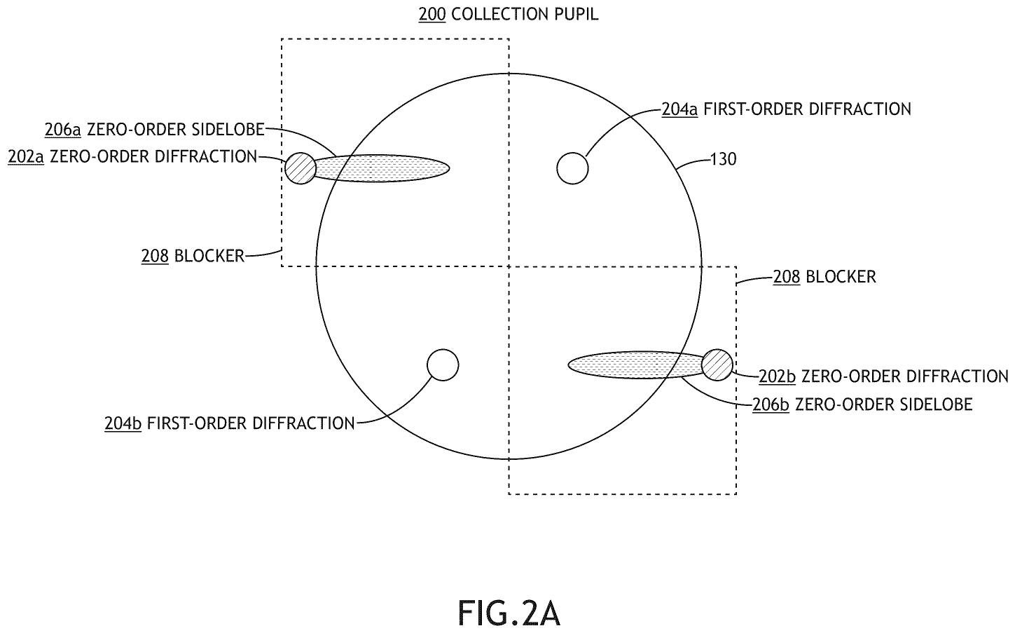

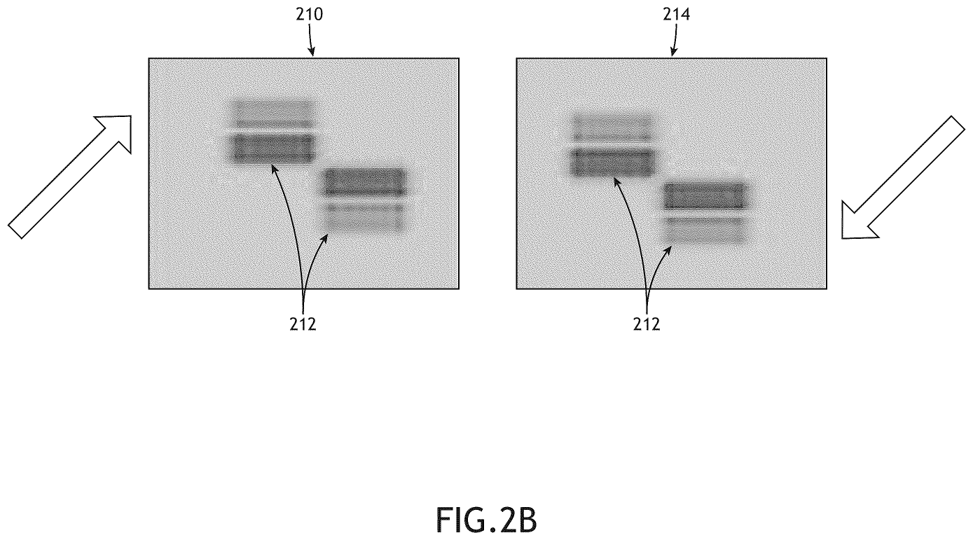

More generally, the focusing system 100 may split the sample light 116 such that the images generated by the different detectors 114 (e.g., the first detector 114a and the second detector 114b) are generated with different illumination conditions, where the different illumination conditions are selected to provide lateral shifts of imaged features when the sample 102 is not at the focal plane of the imaging system 104. Non-limiting examples of such different illumination conditions are described in greater detail with respect to FIGS. 2A-4 below.

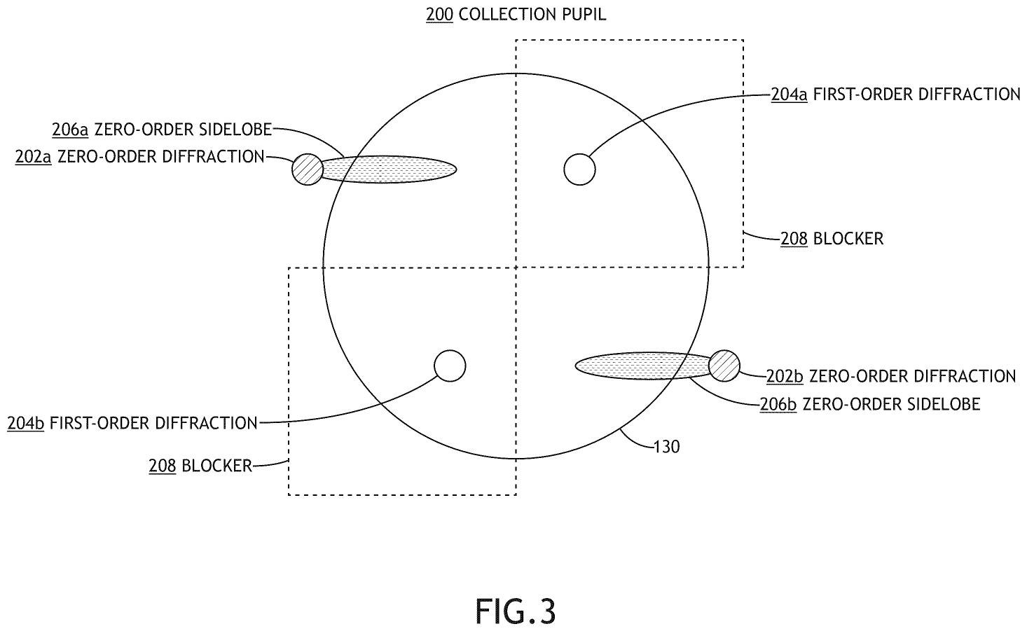

Referring to FIGS. 2A-3, in some embodiments, focus detection is performed by generating a first image using sample light 116 from a first illumination beam 110a and a second image using sample light 116 from the second illumination beam 110b. The first image and the second image may be generated sequentially (e.g., using the configuration in FIG. 1C) or simultaneously (e.g., using the configuration in FIG. 1D). Further, it may be desirable to generate the first image and the second image using light corresponding to a single diffraction order or sidelobes associated with a single diffraction order. For example, FIGS. 2A-2B depict imaging based on first-order diffraction. As another example, FIG. 3 depicts imaging based on zero-order diffraction and/or zero-order sidelobes.

FIG. 2A illustrates a collection pupil 200 of an imaging system 104 depicting various diffraction orders from periodic features on a sample 102, in accordance with one or more embodiments of the present disclosure. In particular, the collection pupil 200 includes a distribution of diffraction orders generated from the first illumination beam 110a and the second illumination beam 110b in the configurations of the focusing system 100 shown in FIG. 1C or 1D, where features on the sample 102 have periodicity along a horizontal direction in the figure, and where azimuth angles of the first illumination beam 110a and the second illumination beam 110b are rotated relative to the direction of periodicity.

For clarity of illustration, the diffraction orders with reference numbers ending in “a” are associated with the first illumination beam 110a, while the diffraction orders with reference numbers ending in “b” are associated with the second illumination beam 110b. In particular, FIG. 2A depicts zero-order diffraction 202a and zero-order diffraction 202b, which lie outside of a collection numerical aperture of the objective lens 130 based on the OTL configuration shown in FIGS. 1C and 1D. FIG. 2A further depicts zero-order sidelobe 206a and zero-order sidelobe 206b that extend outward from their respective zero-order diffraction poles and may be at least partially captured by the objective lens 130. FIG. 2A further depicts first-order diffraction 204a and first-order diffraction 204b.

As described above, it may be desirable to select light associated with a single diffraction order for imaging and focus determination. FIG. 2A shows an example configuration including blockers 208 positioned to pass the first-order diffraction 204a, 204b and block the zero-order diffraction 202a, 202b along with the zero-order sidelobes 206a, 206b.

FIG. 2B illustrates two images captured using different illumination conditions depicting lateral shifts of imaged features when the sample 102 is not at the focal plane of the imaging system 104, in accordance with one or more embodiments of the present disclosure. FIG. 2B depicts the concept of lateral shift detection. For example, a first image 210 may be generated based on the first-order diffraction 204a from the first illumination beam 110a, while a second image 214 may be generated based on first-order diffraction 204b from the second illumination beam 110b. As shown in FIG. 2B, defocus of the sample 102 results in opposing lateral shifts of the imaged features 212 (e.g., here, portions of a metrology target), where the opposing lateral shifts occur along a direction corresponding to an orientation of the selected diffraction orders in the collection pupil 200. For example, the imaged features 212 exhibit a opposing lateral shifts along a direction of separation of the first-order diffraction 204a and the first-order diffraction 204b shown in FIG. 2A. Further, the directions of the lateral shifts may be indicative of whether the sample 102 is above or below the focal plane.

The lateral shift of the imaged features 212 between the first image and the second image may be measured and used to determine a measurement of the focal position of the sample 102 using any suitable technique. In some embodiments, the lateral shift is calculated by maximizing a two-dimensional correlation integral of the two images.

The focus position may then be calculated using a formula that includes the lateral shift. For example, the focus position (z) may be calculated using the following formula:

$$z = \frac{1}{4} \sqrt{1 - {na}_{x}^{2} - {na}_{y}^{2}} ( \frac{{x}_{0}}{{na}_{x}} + \frac{{y}_{0}}{{na}_{y}} ) \qquad ( 1 )$$

where (naₓ, na_{y}) represents the positions of the center lobes of the first orders (e.g., positions of the first-order diffraction 204a and the first-order diffraction 204b in the collection pupil 200) and (x₀, y₀) represents the lateral shift between the first image 210 and the second image 214. These pupil positions (naₓ, na_{y}) may be determined using any technique and in some cases may be extracted from a fringe direction and effective periodicity of an image generated using mutually-coherent illumination beams (e.g., a separate image using both the first illumination beam 110a and the second illumination beam 110b). It is noted that Equation (1) may in some cases be exact up to the second order in the defocus phase Taylor expansion around (naₓ, na_{y}).

Referring now to FIG. 3, in some embodiments, the use of zero-order light for the focus determination is described.

FIG. 3 illustrates a collection pupil 200 of an imaging system 104 depicting various diffraction orders from periodic features on a sample 102, in accordance with one or more embodiments of the present disclosure. FIG. 3 is similar to FIG. 2A except that FIG. 3 shows a configuration where blockers 208 are positioned to pass zero-order light (e.g., zero-order diffraction 202a, 202b and/or zero-order sidelobes 206a, 206b) and block first-order light (e.g., first-order diffraction 204a, 204b).

In this configuration, sample defocus may induce a lateral shift between imaged features 212 in a first image generated by zero-order diffraction from the first illumination beam 110a and a second image generated by zero-order diffraction from the second illumination beam 110b. However, in contrast to the example shown in FIG. 2B, the lateral shift direction in this case may be associated with a direction of separation between the zero-order diffraction 202a and the zero-order diffraction 202b in the collection pupil 200 shown in FIG. 3. Further, the focus position (z) may be calculated using Equation (1), where (naₓ, na_{y}) in this case represents the positions of the center lobes of the zero-order diffraction 202a and the zero-order diffraction 202b in the collection pupil 200.

This approach may be applied to multiple aspects of zero-order light. In some embodiments, only the zero-order sidelobes 206a and the zero-order sidelobes 206b may be captured and used to generate the first and second images. For example, FIG. 3 shows an OTL configuration in which zero-order sidelobes 206a, 206b) are captured by the objective lens 130, but the center lobes of the zero-order diffraction 202a, 202b are not. In this case, (naₓ, na_{y}) in Equation (1) still represents the positions of the center lobes of the zero-order diffraction 202a and the zero-order diffraction 202b in the collection pupil 200. In some embodiments, the zero-order diffraction 202a, 202b may be fully captured and used for image generation. In some cases, this may be achieved using a TTL configuration.

Additionally, in some embodiments, it may be desirable to utilize the first-order diffraction 204a,204b for a metrology measurement. In this case, instead of providing blockers 208 to block the first-order diffraction 204a,204b in the collection pupil 200, splitting optics (e.g., a knife-edge prism, mirrors, or the like) may be used to direct the zero-order light (e.g., the zero-order sidelobes 206a, 206b to one detector 114 and direct the first-order diffraction 204a,204b to another detector 114. These splitting optics may be placed in any suitable location including, but not limited to, a collection pupil.

In some cases, the zero-order diffraction 202a, 202b may be directly captured in an OTL configuration. For example, although not shown, additional beamsplitters may be added in the illumination system 106 (e.g., as shown in the OTL configurations of FIGS. 1C-1D) that may capture and redirect the zero-order diffraction 202a, 202b associated with opposing illumination beams. The zero-order diffraction 202a, 202b may then be separately imaged (e.g., sequentially on a common detector 114 or simultaneously on two detectors 114). The focal position can then be extracted from Equation (1), with (naₓ, na_{y}) again corresponding to the position of the center lobes of the zero-order diffraction 202a, 202b.

FIG. 1E illustrates a focusing system 100 including beamsplitters 138 to capture zero-order diffraction 202a, 202b in an OTL configuration, in accordance with one or more embodiments of the present disclosure. For example, FIG. 1E depicts a configuration with a first detector 114a associated with the imaging system 104, and two additional detectors 114b, 114c to image the sample 102 based on zero-order diffraction 202a, 202b from the beamsplitters 138. In this configuration, the values of (naₓ, na_{y}) are associated with positions of the center lobes of the zero-order diffraction 202a, 202b in a common collection pupil. For example, the values of (naₓ, na_{y}) may be extracted based on an image of the sample 102 using the first detector 114a.

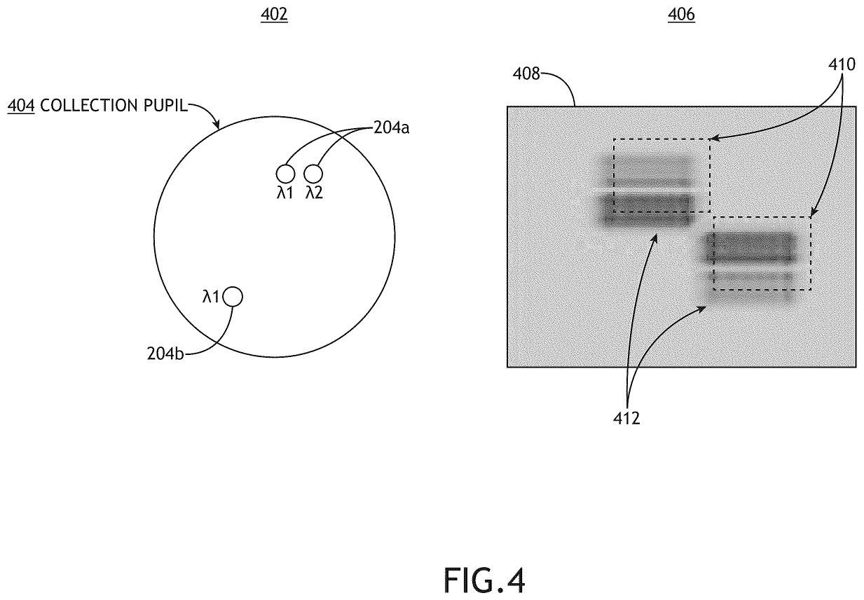

Referring now to FIG. 4, focus determination based on a single image generated with multiple illumination conditions is described. Mutual lateral shifts of imaged features, and thus a focal position, may be inferred from a single image that includes diffraction orders from both the first illumination beam 110a and the second illumination beam 110b. However, determining whether the sample 102 is above or below the focal plane of the imaging system 104 may require differentiation between the first illumination beam 110a and the second illumination beam 110b.

The first illumination beam 110a and the second illumination beam 110b may be distinguished based on any properties including, but not limited to, wavelength, polarization, or intensity.

FIG. 4 illustrates wavelength discrimination between the first illumination beam 110a and the second illumination beam 110b for focus detection from a single image, in accordance with one or more embodiments of the present disclosure.

In some embodiments, both the first illumination beam 110a and the second illumination beam 110b may include mutually-coherent light at one or more first wavelengths (represented by λ1), while the first illumination beam 110a may additionally include light at one or more second wavelengths (represented by λ2). Panel 402 illustrates a collection pupil 404 including first-order diffraction 204a, 204b generated based on the first illumination beam 110a and the second illumination beam 110b.

This illumination configuration may create an incoherent superposition of a first sub-image 410 and a second sub-image 412, where the first sub-image 410 is generated based on the mutually-coherent light at the one or more first wavelengths, and where the second sub-image 412 is generated based only on the light at the one or more second wavelengths from the first illumination beam 110a.

The different wavelengths in the first illumination beam 110a and second illumination beam 110b may be provided using any suitable technique. For example, an illumination source providing both the first wavelengths and the second wavelengths may generate the first illumination beam 110a and the second illumination beam 110b, where a spectral filter may then filter the second wavelengths from the second illumination beam 110b. This filtering may be achieved using, for example, optical filters, dichroic mirrors, or other wavelength-selective optical components positioned in the optical path of the second illumination beam 110b. As another example, one illumination source may generate the mutually-coherent light at the first wavelengths in both the first illumination beam 110a and the second illumination beam 110b and another illumination source may generate additional light at the second wavelengths, which may be spectrally combined with the first illumination beam 110a using any components including, but not limited to, beam combiners, fiber couplers, or other optical combining elements.

Panel 406 includes a single image 408 generated based on simultaneous illumination of the sample 102 with the first illumination beam 110a and the second illumination beam 110b, where the single image 408 includes a first sub-image 410 based on the mutually-coherent light at the one or more first wavelengths and a second sub-image 412 based only on the one or more second wavelengths in the first illumination beam 110a. In the image 408, only the locations of the first sub-image 410 are shown and are represented as dotted lines for clarity.

In this configuration, the focal position may be determined using Equation (1), noting that the positions of the center lobes of the first orders (naₓ, na_{y}) vary as a function of wavelength (e.g., as shown in panel 402). For example, when using first diffraction order, naₓ corresponds to naₓ=−na_{x,0}+λ/pitch, where λ is wavelength, pitch is the pitch of features on the sample 102 that inducing the diffraction, and na_{x,0} corresponds to the pupil coordinates of the illumination beam (e.g., the first illumination beam 110a or the second illumination beam 110b).

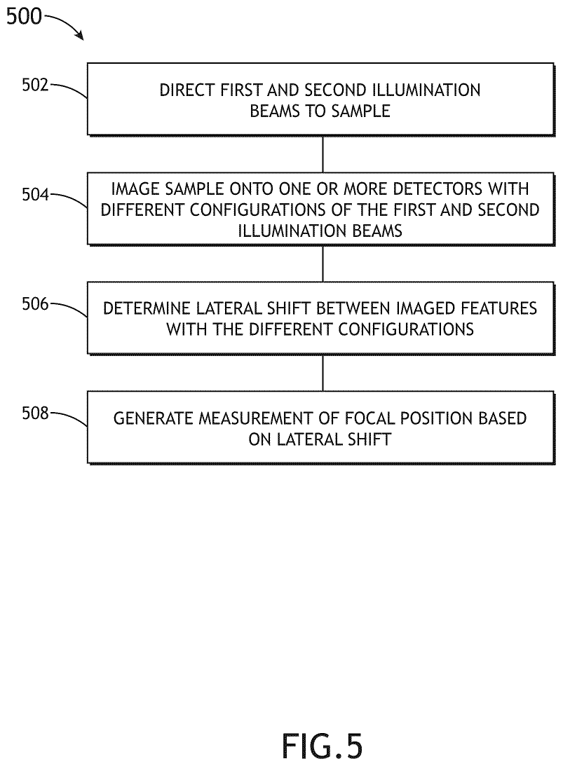

Referring now to FIG. 5, methods for focus measurement are described. FIG. 5 illustrates a method 500 for focus detection, in accordance with one or more embodiments of the present disclosure. The embodiments and enabling technologies described in the context of the focusing system 100 may be extended to the method 500. However, the method 500 is not limited to the architecture of the focusing system 100.

The method 500 may include a step 502 of directing a first illumination beam and a second illumination beam to a sample at opposing azimuth angles. In some cases, the first illumination beam and the second illumination beam may be directed to the sample by the illumination system 106 of the focusing system 100. For example, the illumination lenses 108 may focus the first illumination beam and the second illumination beam onto the sample 102 at opposing azimuth angles. In some implementations, the first illumination beam and the second illumination beam may be mutually coherent at one or more first wavelengths. In some cases, the first illumination beam may additionally include one or more second wavelengths.

The method 500 may include a step 504 of imaging the sample onto one or more detectors with different configurations of the first illumination beam and the second illumination beam. In some cases, the imaging system 104 may image the sample 102 onto the one or more detectors 114. For example, the collection lenses 112 may collect sample light 116 from the sample 102 and direct the sample light 116 to the one or more detectors 114.

In some embodiments, the method 500 may generate two separate images. For instance, a first image may be generated based on the first illumination beam and a second image may be generated based on the second illumination beam. These images may be generated sequentially on a single detector or simultaneously on separate detectors. In some embodiments, the method 500 may generate a single image that includes information from both illumination beams. For example, the single image may include a first sub-image generated with mutually coherent light from both illumination beams and a second sub-image generated with light at one or more second wavelengths from only the first illumination beam.

The method 500 may include a step 506 of determining a lateral shift between locations of features on the sample imaged by different combinations of the first illumination beam and the second illumination beam. In some cases, the controller 120 may determine the lateral shift based on one or more images received from the one or more detectors 114. For implementations using two separate images, the controller 120 may receive a first image and a second image from the one or more detectors 114 and determine the lateral shift by comparing the positions of imaged features in the first image and the second image. For implementations using a single image, the lateral shift may be determined by comparing the positions of imaged features in the first sub-image and the second sub-image. For example, the controller 120 may receive a single image from a detector 114 that includes the first sub-image and the second sub-image and then determine the lateral shift by comparing positions of imaged features in the first sub-image and the second sub-image. The lateral shift may be determined based on images generated with any selected diffraction orders. In some cases, the lateral shift may be determined using first-order diffraction from the sample. In other cases, the lateral shift may be determined using zero-order diffraction or zero-order sidelobes from the sample.

The method 500 may include a step 508 of generating a measurement of a focal position of the sample based on the lateral shift. In some cases, the controller 120 may generate the focal position measurement based on the determined lateral shift. For example, the focal position may be calculated using a formula that includes the lateral shift and positions of diffraction orders in a collection pupil of the imaging system. The formula may vary depending on which diffraction orders are used for imaging.

In some implementations, the method 500 may further include adjusting the focal position of the sample based on the measurement. For example, the controller 120 may direct the actuators 118 to adjust the position of the sample 102 or components of the imaging system 104 to achieve a desired focal position.

In some embodiments, the method 500 may be performed by a dedicated focusing system 100. In some embodiments, the method 500 may be performed by a metrology system 126 with an integrated focusing system 100. In this way, the method 500 may provide focus detection without requiring additional dedicated focus detection hardware.

In some embodiments, after adjusting the focal position of the sample, the focusing system may be used to generate one or more metrology measurements. These metrology measurements may include, but are not limited to, overlay measurements, critical dimension (CD) measurements, film thickness measurements, or material composition measurements.

Any of the methods described herein may include storing results of one or more steps of the method embodiments in memory. The results may include any of the results described herein and may be stored in any manner known in the art. The memory may include any memory described herein or any other suitable storage medium known in the art. After the results have been stored, the results can be accessed in the memory and used by any of the method or system embodiments described herein, formatted for display to a user, used by another software module, method, or system, and the like. Furthermore, the results may be stored “permanently,” “semi-permanently,” temporarily,” or for some period of time. For example, the memory may be random access memory (RAM), and the results may not necessarily persist indefinitely in the memory.

It is further contemplated that each of the embodiments of the method described above may include any other step(s) of any other method(s) described herein. In addition, each of the embodiments of the method described above may be performed by any of the systems described herein.

One skilled in the art will recognize that the herein described components operations, devices, objects, and the discussion accompanying them are used as examples for the sake of conceptual clarity and that various configuration modifications are contemplated. Consequently, as used herein, the specific exemplars set forth and the accompanying discussion are intended to be representative of their more general classes. In general, use of any specific exemplar is intended to be representative of its class, and the non-inclusion of specific components, operations, devices, and objects should not be taken as limiting.

As used herein, directional terms such as “top,” “bottom,” “over,” “under,” “upper,” “upward,” “lower,” “down,” and “downward” are intended to provide relative positions for purposes of description, and are not intended to designate an absolute frame of reference. Various modifications to the described embodiments will be apparent to those with skill in the art, and the general principles defined herein may be applied to other embodiments.

With respect to the use of substantially any plural and/or singular terms herein, those having skill in the art can translate from the plural to the singular and/or from the singular to the plural as is appropriate to the context and/or application. The various singular/plural permutations are not expressly set forth herein for sake of clarity.

The herein described subject matter sometimes illustrates different components contained within, or connected with, other components. It is to be understood that such depicted architectures are merely exemplary, and that in fact many other architectures can be implemented which achieve the same functionality. In a conceptual sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermedial components. Likewise, any two components so associated can also be viewed as being “connected,” or “coupled,” to each other to achieve the desired functionality, and any two components capable of being so associated can also be viewed as being “couplable,” to each other to achieve the desired functionality. Specific examples of couplable include but are not limited to physically mateable and/or physically interacting components and/or wirelessly interactable and/or wirelessly interacting components and/or logically interacting and/or logically interactable components.

Furthermore, it is to be understood that the invention is defined by the appended claims. It will be understood by those within the art that, in general, terms used herein, and especially in the appended claims (e.g., bodies of the appended claims) are generally intended as “open” terms (e.g., the term “including” should be interpreted as “including but not limited to,” the term “having” should be interpreted as “having at least,” the term “includes” should be interpreted as “includes but is not limited to,” and the like). It will be further understood by those within the art that if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to inventions containing only one such recitation, even when the same claim includes the introductory phrases “one or more” or “at least one” and indefinite articles such as “a” or “an” (e.g., “a” and/or “an” should typically be interpreted to mean “at least one” or “one or more”); the same holds true for the use of definite articles used to introduce claim recitations. In addition, even if a specific number of an introduced claim recitation is explicitly recited, those skilled in the art will recognize that such recitation should typically be interpreted to mean at least the recited number (e.g., the bare recitation of “two recitations,” without other modifiers, typically means at least two recitations, or two or more recitations). Furthermore, in those instances where a convention analogous to “at least one of A, B, and C, and the like” is used, in general such a construction is intended in the sense one having skill in the art would understand the convention (e.g., “a system having at least one of A, B, and C” would include but not be limited to systems that have A alone, B alone, C alone, A and B together, A and C together, B and C together, and/or A, B, and C together, and the like). In those instances where a convention analogous to “at least one of A, B, or C, and the like” is used, in general such a construction is intended in the sense one having skill in the art would understand the convention (e.g., “a system having at least one of A, B, or C” would include but not be limited to systems that have A alone, B alone, C alone, A and B together, A and C together, B and C together, and/or A, B, and C together, and the like). It will be further understood by those within the art that virtually any disjunctive word and/or phrase presenting two or more alternative terms, whether in the description, claims, or drawings, should be understood to contemplate the possibilities of including one of the terms, either of the terms, or both terms. For example, the phrase “A or B” will be understood to include the possibilities of “A” or “B” or “A and B.”

It is believed that the present disclosure and many of its attendant advantages will be understood by the foregoing description, and it will be apparent that various changes may be made in the form, construction and arrangement of the components without departing from the disclosed subject matter or without sacrificing all of its material advantages. The form described is merely explanatory, and it is the intention of the following claims to encompass and include such changes. Furthermore, it is to be understood that the invention is defined by the appended claims.

What is claimed:

1. A focus detection system comprising:
an illumination system including one or more illumination lenses configured to direct a first illumination beam and a second illumination beam to a sample at opposing azimuth angles;
an imaging system including one or more collection lenses configured to image the sample onto one or more detectors; and
a controller including one or more processors configured to execute program instructions causing the one or more processors to:
determine a lateral shift between locations of features on the sample imaged by different configurations of the first illumination beam and the second illumination beam; and
generate a measurement of a focal position of the sample based on the lateral shift.

2. The focus detection system of claim 1, wherein the one or more illumination lenses direct the first illumination beam and the second illumination beam to the sample by illumination optics outside of a numerical aperture of an objective lens in the imaging system.

3. The focus detection system of claim 1, wherein determining the lateral shift between locations of features on the sample imaged by different combinations of the first illumination beam and the second illumination beam comprises:
receiving a first image of the features on the sample imaged with the first illumination beam;
receiving a second image of the features on the sample imaged with the second illumination beam; and
determining the lateral shift based on the first image and the second image.

4. The focus detection system of claim 3, wherein the one or more detectors comprise a single detector, wherein the first image and the second image are generated by the single detector sequentially based on sequential illumination of the sample with the first illumination beam and the second illumination beam.

5. The focus detection system of claim 3, wherein the imaging system includes one or more splitting optics to direct light from the sample associated with the first illumination beam along a first path for generation of the first image and to direct light from the sample associated with the second illumination beam along a second path for generation of the second image, wherein the first image and the second image are generated simultanteously based on simultaneous illumination of the sample with the first illumination beam and the second illumination beam.

6. The focus detection system of claim 5, wherein the first image and the second image are generated on separate detectors of the one or more detectors.

7. The focus detection system of claim 5, wherein the first image and the second image are generated on nonoverlapping regions of common detector of the one or more detectors.

8. The focus detection system of claim 5, wherein the one or more splitting optics comprise a splitting prism located in a collection pupil of the imaging system.

9. The focus detection system of claim 3, wherein the first image is generated based on first-order diffraction of the first illumination beam by the sample, wherein the second image is generated based on first-order diffraction of the second illumination beam by the sample.

10. The focus detection system of claim 3, wherein the first image is generated based on zero-order diffraction of the first illumination beam by the sample, wherein the second image is generated based on zero-order diffraction of the second illumination beam by the sample.

11. The focus detection system of claim 10, wherein the one or more illumination lenses direct the first illumination beam and the second illumination beam to the sample by illumination optics outside of a numerical aperture of an objective lens in the imaging system, wherein the illumination optics include beamsplitters to collect the zero-order diffraction of the first illumination beam and the zero-order diffraction of the second illumination beam for generation of the first image and the second image.

12. The focus detection system of claim 3, wherein the first image is generated based on zero-order sidelobes associated with the first illumination beam from the sample, wherein the second image is generated based on zero-order sidelobes associated with the second illumination beam from the sample.

13. The focus detection system of claim 1, wherein the first illumination beam and the second illumination beam are mutually coherent at one or more first wavelengths, wherein the first illumination beam includes one or more second wavelengths, wherein determining the lateral shift between locations of features on the sample imaged by different combinations of the first illumination beam and the second illumination beam comprises:
receiving a single image of the features on the sample, wherein the single image includes a first sub-image of the features generated with the one or more first wavelengths from the first illumination beam and the second illumination beam, wherein the single image further includes a second sub-image of the features generated with the one or more second wavelengths from the first illumination beam; and
determining the lateral shift based on the first sub-image and the second sub-image.

14. The focus detection system of claim 13, wherein the first sub-image is generated based on first-order diffraction of the one or more first wavelengths by the sample, wherein the second sub-image is generated based on first-order diffraction of the one or more second wavelengths by the sample.

15. The focus detection system of claim 13, wherein the first sub-image is generated based on zero-order diffraction of the one or more first wavelengths by the sample, wherein the second sub-image is generated based on zero-order diffraction of the one or more second wavelengths by the sample.

16. The focus detection system of claim 15, wherein the one or more illumination lenses direct the first illumination beam and the second illumination beam to the sample by illumination optics outside of a numerical aperture of an objective lens in the imaging system, wherein the illumination optics include beamsplitters to collect the zero-order diffraction of the first illumination beam and the zero-order diffraction of the second illumination beam for generation of the first sub-image and the second sub-image.

17. The focus detection system of claim 13, wherein the first sub-image is generated based on zero-order sidelobes associated with the one or more first wavelengths by the sample, wherein the second sub-image is generated based on zero-order sidelobes associated with the one or more second wavelengths by the sample.

18. A focus detection method comprising:
directing a first illumination beam and a second illumination beam to a sample at opposing azimuth angles with an illumination system;
imaging the sample onto one or more detectors with different configurations of the first illumination beam and the second illumination beam;
determining a lateral shift between locations of features on the sample imaged by different combinations of the first illumination beam and the second illumination beam; and
generating a measurement of a focal position of the sample based on the lateral shift.

19. A metrology system comprising:
an illumination system including one or more illumination lenses configured to direct a first illumination beam and a second illumination beam to a sample at opposing azimuth angles;
an imaging system including one or more collection lenses configured to image the sample onto one or more detectors;
one or more actuators to adjust a focal position of the sample; and
a controller including one or more processors configured to execute program instructions causing the one or more processors to:
determine a lateral shift between locations of features on the sample imaged by different configurations of the first illumination beam and the second illumination beam;
generate a measurement of the focal position of the sample based on the lateral shift;
direct the one or more actuators to adjust the focal position of the sample to a desired setting based on the measurement;
receive one or more images of the sample from at least one of the one or more detectors; and
generate one or more metrology measurements of the sample based on the one or more images.

20. The metrology system of claim 19, wherein determining the lateral shift between locations of features on the sample imaged by different combinations of the first illumination beam and the second illumination beam comprises:
receiving a first image of the features on the sample imaged with the first illumination beam;
receiving a second image of the features on the sample imaged with the second illumination beam; and
determining the lateral shift based on the first image and the second image.

21. The metrology system of claim 19, wherein the first illumination beam and the second illumination beam are mutually coherent at one or more first wavelengths, wherein the first illumination beam includes one or more second wavelengths, wherein determining the lateral shift between locations of features on the sample imaged by different combinations of the first illumination beam and the second illumination beam comprises:
receiving a single image of the features on the sample, wherein the single image includes a first sub-image of the features generated with the one or more first wavelengths from the first illumination beam and the second illumination beam, wherein the single image further includes a second sub-image of the features generated with the one or more second wavelengths from the first illumination beam; and
determining the lateral shift based on the first sub-image and the second sub-image.

22. The metrology system of claim 19, wherein the one or more metrology measurements comprise one or more overlay measurements.
